(19) United States
(12) Patent Application Publication
(10) Pub. No.: US 2026/0198116 A1
(43) Pub. Date: Jul. 9, 2026

(54) IMAGE SENSOR

(71) Applicant: VisEra Technologies Company Ltd., Hsin-Chu City (TW)

(72) Inventors: Shin-Hong KUO, Hsin-Chu City (TW); Ching-Hua LI, Hsin-Chu City (TW); Po-Hsiang WANG, Hsin-Chu City (TW); Han-Lin WU, Hsin-Chu City (TW); Hung-Jen TSAI, Hsin-Chu City (TW)

(21) Appl. No.: 19/237,288

(22) Filed: Jun. 13, 2025

Related U.S. Application Data
(60) Provisional application No. 63/741,617, filed on Jan. 3, 2025.

(51) Int. Cl. H10F 39/00; G02B 1/11; G02B 27/00; H10F 39/18

(52) U.S. Cl. CPC H10F 39/805; G02B 1/11; G02B 27/0018; H10F 39/182; H10F 39/8053; H10F 39/807

(57) ABSTRACT

An image sensor includes a photoelectric conversion layer, a color filter layer, an extension layer, an enhanced layer, a first pillar layer, a propagation layer, and a router layer. The enhanced layer includes a plurality of enhanced portions disposed on the extension layer. The first pillar layer includes a plurality of first pillars disposed on the enhanced layer, wherein each of the first pillars corresponds to each of the enhanced portions. The propagation layer is disposed on the extension layer and the first pillar layer, wherein the propagation layer surrounds the first pillars and the enhanced portions. The router layer is disposed on the propagation layer, wherein the router layer includes a transmission layer including a plurality of microstructures.

### CROSS-REFERENCE TO RELATED APPLICATION

This application claims priority to U.S. Provisional Application Ser. No. 63/741,617, filed Jan. 3, 2025, which is herein incorporated by reference in its entirety.

### BACKGROUND

### Field of Invention

The present disclosure relates to an image sensor. More particularly, the present disclosure relates to the image sensor having an enhanced layer and an extension layer.

### Description of Related Art

Traditional meta-surface complementary metal oxide semiconductor (CMOS) image sensors (also known as CIS) have high reflections, which decreases the optical efficiency of CIS. High reflections may be occurred between different layers and therefore causes optical flares or ghost images. Specifically, interfaces between different layers with high refractive index differences cause high reflections and decrease of the quantum efficiency of CIS. Therefore, there is a need to solve the above problems.

### SUMMARY

The image sensor of the present disclosure has a transmission layer, a propagation layer, a first pillar layer, an enhanced layer, and an extension layer. The transmission layer includes a plurality of microstructures which can reduce the external light to be reflected. The propagation layer surrounds a plurality of first pillars of the first pillar layer, a plurality of the enhanced portions of the enhanced layer, and a plurality of the protruding portions of the extension layer, so that the quantum efficiency of the image sensor can be improved. In addition, the shape of each protruding portion of the extension layer follows the shape of each of the first pillar, therefore the refractive index differences different layers can be decreased and so the quantum efficiency of the image sensor can be increased.

One aspect of the present disclosure is to provide an image sensor. The image sensor includes a photoelectric conversion layer, a color filter layer, an extension layer, an enhanced layer, a first pillar layer, a propagation layer, and a router layer. The color filter layer is disposed on the photoelectric conversion layer. The extension layer is disposed on the color filter layer. The enhanced layer includes a plurality of enhanced portions disposed on the extension layer. The first pillar layer includes a plurality of first pillars disposed on the enhanced layer, wherein each of the first pillars corresponds to each of the enhanced portions. The propagation layer is disposed on the extension layer and the first pillar layer, wherein the propagation layer surrounds the first pillars and the enhanced portions. The router layer is disposed on the propagation layer, wherein the router layer includes a transmission layer including a plurality of microstructures, wherein a height of each of the enhanced portions satisfies the following formula:

$$0.02 \times λ \leq {H}_{E N P} \leq 0.85 \times {H}_{P 1} - 40 ,$$

wherein λ is a wavelength of an external light, H_{ENP} is the height of each of the enhanced portions, and H_{P1} is a height of each of the first pillars.

According to some embodiments of the present disclosure, a bottom surface of one of the first pillars contacts a top surface of one of the enhanced portions, and a bottom surface area of one of the first pillars is substantially the same as a top surface area of one of the enhanced portions.

According to some embodiments of the present disclosure, a refractive index of the propagation layer is less than or equal to a refractive index of the extension layer.

According to some embodiments of the present disclosure, a refractive index of the propagation layer is in a range from 1.2 to 1.7.

According to some embodiments of the present disclosure, a refractive index of the enhanced layer satisfies the following formula:

$${( {n}_{P 1} \times {n}_{E X} - 1.4 )}^{0.5} \leq {n}_{E N} \leq {( {n}_{P 1} \times {n}_{E X} + 1.6 )}^{0.5} ,$$

wherein n_{P1} is a refractive index of the first pillar layer, n_{EX} is a refractive index of the extension layer, and n_{EN} is the refractive index of the enhanced layer.

According to some embodiments of the present disclosure, a maximum height of the extension layer is in a range from 100 nm to 2800 nm.

According to some embodiments of the present disclosure, the extension layer includes a main portion and a plurality of protruding portions protruding from the main portion, where the main portion is disposed between the protruding portions and the color filter layer, and each of the protruding portions corresponds to each of the enhanced portions. The propagation layer disposed on the main portion and surrounds the protruding portions.

According to some embodiments of the present disclosure, a bottom surface of one of enhanced portions contacts a top surface of one of the protruding portions, and a bottom surface area of one of the enhanced portions is substantially the same as a top surface area of one of the protruding portions.

According to some embodiments of the present disclosure, each of the protruding portions has a trapezoidal profile, and an angle between a sidewall and a top surface of each of the enhanced portions is in a range from 90° and 135°.

According to some embodiments of the present disclosure, each of the enhanced portions has a trapezoidal profile, and an angle between a top surface of the main portion and a sidewall of each of the protruding portions is 90°.

According to some embodiments of the present disclosure, an angle between a sidewall and a top surface of each of the enhanced portions is 90°, and an angle between a top surface of the main portion and a sidewall of each of the protruding portions is 90°.

According to some embodiments of the present disclosure, a top portion of each of the first pillars includes an inclined surface, an angle between the inclined surface and a sidewall of the each of the first pillars is greater than or equal to 110°.

According to some embodiments of the present disclosure, a top portion of each of the first pillars includes a round profile, and a corner radius of the round profile is greater than or equal to a radius of each of the first pillars.

According to some embodiments of the present disclosure, the router layer further includes a second pillar layer including a plurality of second pillars surrounded by the propagation layer and connecting the transmission layer, each of the second pillars has an outward extending sidewall, and an angle between the outward extending sidewall and a top surface of the each of the second pillars is in a range from 45° to 90°.

According to some embodiments of the present disclosure, the router layer further includes a second pillar layer including a plurality of second pillars surrounded by the propagation layer and connecting the transmission layer, a bottom portion of each of the second pillars includes an inclined surface, and an angle between the inclined surface and a bottom surface of the each of the second pillars is greater than or equal to 110°.

According to some embodiments of the present disclosure, the router layer further includes a second pillar layer including a plurality of second pillars surrounded by the propagation layer and connecting the transmission layer, each of the second pillars has an outward extending sidewall, an angle between the outward extending sidewall and a top surface of the each of the second pillars is in a range from 45° to 90°, a bottom portion of each of the second pillars includes an inclined surface, and an angle between the inclined surface and a bottom surface of the each of the second pillars is greater than or equal to 110°.

According to some embodiments of the present disclosure, each of the first pillars is a cylinder, a square column, a polygonal column, a cross column, an irregular column, or a hollow column.

According to some embodiments of the present disclosure, the router layer further includes a second pillar layer including a plurality of second pillars surrounded by the propagation layer and connecting the transmission layer. The router layer further includes a third pillar layer including a plurality of third pillars surrounded by the propagation layer and a fourth layer including a plurality of fourth pillars surrounded by the propagation layer. The first pillars, the second pillars, the third pillars, and the fourth pillars are spaced form each other.

According to some embodiments of the present disclosure, the router layer further includes a second pillar layer, a transverse layer, a third pillar layer, and an additional propagation layer. The second pillar layer includes a plurality of second pillars surrounded by the propagation layer. The transverse layer is disposed on the second pillar layer. The third pillar layer includes a plurality of third pillars disposed on the transverse layer. The additional propagation layer is disposed on the transverse layer and surrounds the third pillars, wherein materials of the transverse layer, the first pillar layer, the second pillar layer, and the third pillar layer are the same.

According to some embodiments of the present disclosure, the router layer further includes an anti-reflection layer, a transverse layer, and a second pillar layer. The anti-reflection layer is conformally disposed on the transmission layer. The transverse layer is under the transmission layer and connects the transmission layer. The second pillar layer includes a plurality of second pillars surrounded by the propagation layer, wherein materials of the transverse layer, the first pillar layer, the second pillar layer, and the transmission layer are the same, and a refractive index of the transmission layer is greater than a refractive index of the anti-reflection layer.

According to some embodiments of the present disclosure, each of the microstructures is a truncated cone, a tetrahedron, a pentahedron, or a hexahedron.

According to some embodiments of the present disclosure, the photoelectric conversion layer includes a plurality of photodiodes and a plurality of deep trench isolations separating the photodiodes, a pixel is determined by a distance between midlines of adjacent two of the deep trench isolations, the pixel corresponds to 4, 9, 16, or 25 microstructures of the transmission layer, and the microstructures are arranged in an array.

According to some embodiments of the present disclosure, a refractive index of the transmission layer is in a range from 1.25 to 2.5.

According to some embodiments of the present disclosure, the router layer further includes a second pillar layer including a plurality of second pillars surrounded by the propagation layer and connecting the transmission layer. The second pillars include a first group of the second pillars disposed on a die edge of the image sensor and a second group of the second pillars disposed on a die center of the image sensor, the first pillars include a first group of the first pillars disposed on the die edge of the image sensor and a second group of the first pillars disposed on the die center of the image sensor, a center of the first group of the second pillars is offset relative to a center of the first group of the first pillars in a normal direction, and a center of the second group of the second pillars is aligned with a center of the second group of the first pillars in the normal direction.

According to some embodiments of the present disclosure, the photoelectric conversion layer includes a plurality of photodiodes and a plurality of deep trench isolations separating the photodiodes, a pixel is determined by a distance between midlines of adjacent two of the deep trench isolations, and each of the first pillars spans across a plurality of pixels.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of an image sensor according some embodiments of the present disclosure.

FIG. 2A is an enlargement view of the first pillar, the enhanced portion, and the extension layer of the image sensor in FIG. 1.

FIG. 2B, FIG. 2C, FIG. 2D, FIG. 2E, and FIG. 2F are alternative examples of FIG. 2A.

FIG. 3A is a three-dimensional diagram of the first pillar, the enhanced portion, and the protruding portion of the image sensor in FIG. 1.

FIG. 3B is a top view of the first pillar in FIG. 3A.

FIG. 3C is an alternative example of FIG. 3A.

FIG. 3D is a top view of the first pillar in FIG. 3C.

FIG. 3E is an alternative example of FIG. 3A.

FIG. 3F is a top view of the first pillar in FIG. 3E.

FIG. 3G and FIG. 3H are top views of alternative examples of the first pillar in FIG. 3A.

FIG. 3I, FIG. 3J, and FIG. 3K are three-dimensional diagrams of alternative examples of FIG. 3A.

FIG. 4A, FIG. 4B, and FIG. 4C are alternative examples of the second pillar in FIG. 1.

FIG. 5A is a three-dimensional diagram of the microstructure in FIG. 1.

FIG. 5B is a top view of the microstructure in FIG. 5A.

FIG. 5C is an alternative example of the microstructure in FIG. 5A.

FIG. 5D is a top view of the microstructure in FIG. 5C.

FIG. 5E is an alternative example of the microstructure in FIG. 5A.

FIG. 5F is a top view of the microstructure in FIG. 5E.

FIG. 5G is an alternative example of the microstructure in FIG. 5A.

FIG. 5H is a top view of the microstructure in FIG. 5G.

FIG. 5I is an alternative example of the microstructure in FIG. 5A.

FIG. 5J is a top view of the microstructure in FIG. 5I.

FIG. 5K is an alternative example of the microstructure in FIG. 5A.

FIG. 5L is a top view of the microstructure in FIG. 5K.

FIG. 5M is an alternative example of the microstructure in FIG. 5A.

FIG. 5N is a top view of the microstructure in FIG. 5M.

FIG. 6A is a top view of an image sensor according some embodiments of the present disclosure.

FIG. 6B, FIG. 6C, and FIG. 6D are top views of alternative examples of the image sensor in FIG. 6A.

FIG. 7A, FIG. 7B, and FIG. 7C are top views of the first pillars and the color filter layer according some embodiments of the present disclosure.

FIG. 8 is a cross-sectional view of an image sensor according some embodiments of the present disclosure.

FIG. 9 is a cross-sectional view of an image sensor according some embodiments of the present disclosure.

FIG. 10 is a cross-sectional view of an image sensor according some embodiments of the present disclosure.

FIG. 11 is a schematic diagram of an image sensor according some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

It will be understood that, although the terms “first,” “second,” etc. may be used herein to describe various elements, these elements should not be limited by these terms. These terms are only used to distinguish one element from another. For example, a “first element” may be termed a “second element,” and, similarly, a “second element” may be termed a “first element,” without departing from the scope of the embodiments. As used herein, the term “and/or” includes any and all combinations of one or more of the associated listed items.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

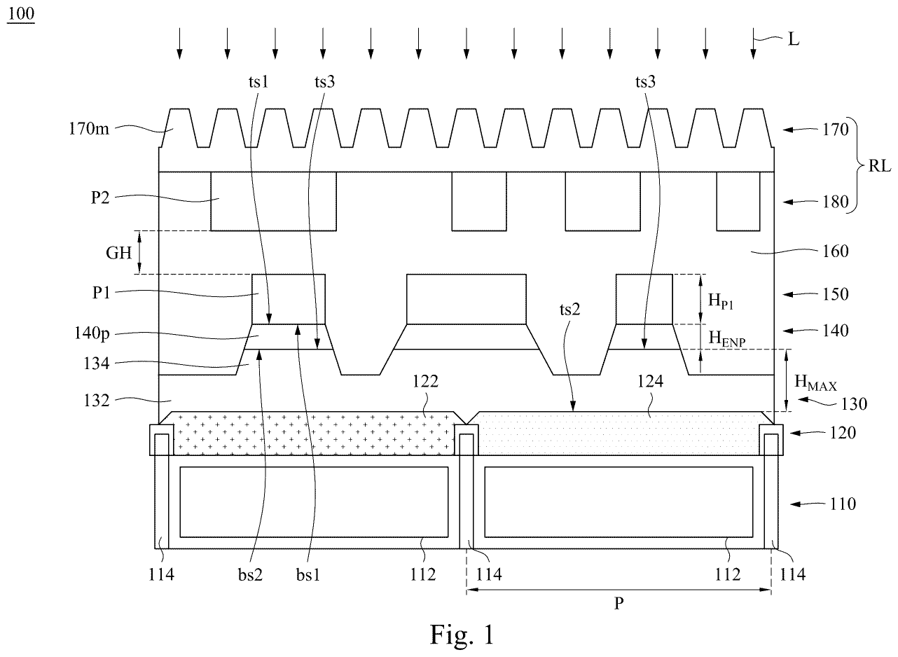

FIG. 1 is a cross-sectional view of an image sensor 100 according some embodiments of the present disclosure. The image sensor 100 includes a photoelectric conversion layer 110, a color filter layer 120, an extension layer 130, an enhanced layer 140, a first pillar layer 150, a propagation layer 160, and a router layer RL. The color filter layer 120 is disposed on the photoelectric conversion layer 110. The extension layer 130 is disposed on the color filter layer 120. The enhanced layer 140 includes a plurality of enhanced portions 140p disposed on the extension layer 130. The first pillar layer 150 includes a plurality of first pillars P1 disposed on the enhanced layer 140, wherein each of the first pillars P1 corresponds to each of the enhanced portions 140p. The propagation layer 160 is disposed on the extension layer 130 and the first pillar layer 150, wherein the propagation layer 160 surrounds the first pillars P1 and the enhanced portions 140p. The router layer RL is disposed on the propagation layer 160, wherein the router layer RL includes a transmission layer 170 including a plurality of microstructures 170m. In some embodiments, a height H_{ENP} of each of the enhanced portions 140p satisfies the following formula:

$$0.02 \times λ \leq {H}_{E N P} \leq 0.85 \times {H}_{P 1} - 40 ,$$

wherein λ is a wavelength of an external light L, H_{ENP} is the height of each of the enhanced portions 140p, and H_{P1} is a height of each of the first pillars P1.

As shown in FIG. 1, the first pillars P1 are separated from each other. One first pillar P1 corresponds to one enhanced portion 140p, and each first pillar P1 stands on each enhanced portion 140p. In some embodiments, a bottom surface bs1 of one of the first pillars P1 contacts a top surface ts1 of one of the enhanced portions 140p. In some embodiments, a bottom surface area of one of the first pillars P1 is substantially the same as a top surface area of one of the enhanced portions 140p. In other words, a projection of the one of the first pillars P1 on the photoelectric conversion layer 110 substantially overlaps a projection of the enhanced portions 140p on the photoelectric conversion layer 110. It could be understood that the sizes of each first pillar P1 and the pitches between the two first pillars P1 can be adjusted according to actual needs.

In some embodiments, a refractive index of the enhanced layer 140 satisfies the following formula:

$${( {n}_{P 1} \times {n}_{E X} - 1.4 )}^{0.5} \leq {n}_{E N} \leq {( {n}_{P 1} \times {n}_{E X} + 1.6 )}^{0.5} ,$$

wherein n_{P1} is a refractive index of the first pillar layer 150, n_{EX} is a refractive index of the extension layer 130, and n_{EN} is the refractive index of the enhanced layer 140. When the refractive index of the enhanced layer 140 satisfies the above formula, the quantum efficiency of the image sensor 100 can be increased. In some embodiments, the refractive index of the enhanced layer 140 is lower than a refractive index of the first pillars P1. The enhanced layer 140 provides the function of anti-reflection and light phase adjustment, thereby increasing the quantum efficiency of the image sensor 100.

In some embodiments, the extension layer 130 includes a main portion 132 and a plurality of protruding portions 134 protruding from the main portion 132. The main portion 132 is disposed between the protruding portions 134 and the color filter layer 120, and each of the protruding portions 134 corresponds to each of the enhanced portions 140p. The propagation layer 160 is disposed on the main portion 132 and surrounds the protruding portions 134. In other words, the propagation layer 160 contacts portions of a top surface of the main portion 132 and sidewalls of the protruding portions 134. Specifically, the protruding portions 134 are separated from each other. More specifically, the protruding portions 134 are separated by the propagation layer 160. The extension layer 130 provides an environment for light phase evolution. The shape of the enhanced portion 140p follows the shape of the first pillar P1 and the shape of the protruding portion 134, which extends the height of the first pillars P1. Specifically, the refractive index differences different layers can be decreased and so the quantum efficiency of the image sensor 100 can be increased.

In some embodiments, a maximum height H_{MAX} of the extension layer 130 is in a range from 100 nm to 2800 nm, such as 500 nm, 1000 nm, 1500 nm, 2000 nm, or 2500 nm. Specifically, the maximum height H_{MAX} is defined by a distance between a top surface ts2 of the color filter layer 120 and a top surface ts3 of one of the protruding portions 134, as shown in FIG. 1. When the maximum height H_{MAX} is in the above range, the quantum efficiency of the image sensor 100 can be increased.

In some embodiments, a bottom surface bs2 of one of enhanced portions 140p contacts the top surface ts3 of one of the protruding portions 134. In some embodiments, a bottom surface area of one of the enhanced portions 140p is substantially the same as a top surface area of one of the protruding portions 134. In other words, a projection of the one of the enhanced portions 140p on the photoelectric conversion layer 110 substantially overlaps a projection of the protruding portions 134 on the photoelectric conversion layer 110.

In some embodiments, a refractive index of the propagation layer 160 is less than a refractive index of the extension layer 130. In some embodiments, a refractive index of the propagation layer 160 is equal to a refractive index of the extension layer 130. In some embodiments, a refractive index of the propagation layer 160 is in a range from 1.2 to 1.7, such as 1.3, 1.4, 1.5, or 1.6. When the refractive index of the propagation layer 160 is in the above range, it is beneficial for improving the quantum efficiency of the image sensor 100.

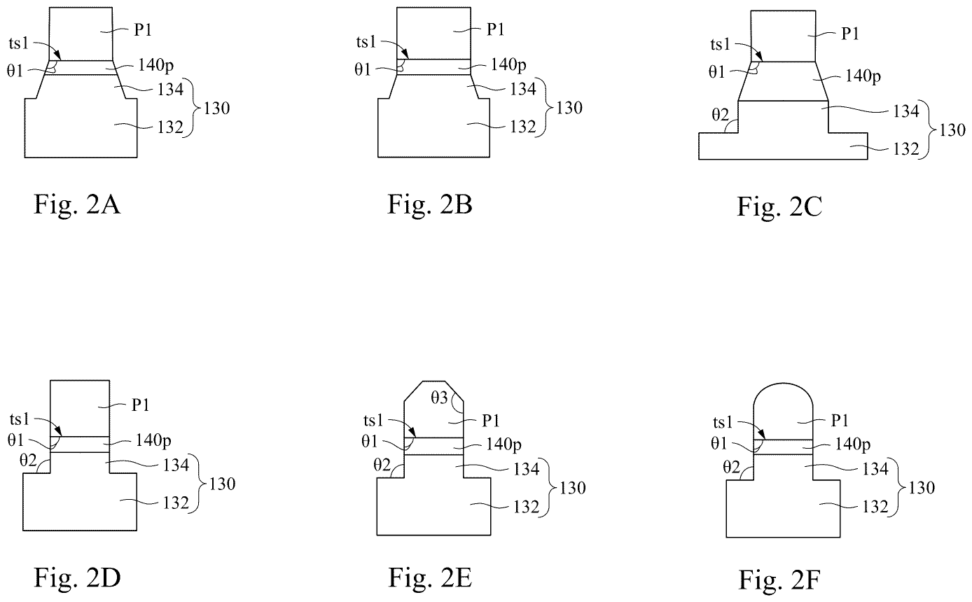

FIG. 2A is an enlargement view of the first pillar P1, the enhanced portion 140p, and the extension layer 130 of the image sensor 100 in FIG. 1. FIG. 2B, FIG. 2C, FIG. 2D, FIG. 2E, and FIG. 2F are alternative examples of FIG. 2A.

In FIG. 2A and FIG. 2B, the protruding portion 134 has a trapezoidal profile, and an angle θ1 between a sidewall and the top surface ts1 of the enhanced portion 140p is in a range from 90° and 135°. In FIG. 2A, the angle θ1 is greater than 90° and up to a maximum of 135°, and the enhanced portion 140p has a trapezoidal profile. In FIG. 2B, the angle θ1 is 90°, and the enhanced portion 140p has a rectangular profile.

In FIG. 2C, the enhanced portion 140p has a trapezoidal profile, and an angle θ2 between a top surface of the main portion 132 and a sidewall of the protruding portion 134 is 90°. The protruding portion 134 in FIG. 2C has a rectangular profile.

In FIG. 2D, the angle θ1 between the sidewall and the top surface of the enhanced portion 140p is 90°, and the angle θ1 between the top surface of the main portion 132 and the sidewall of the protruding portion 134 is 90°. As shown in FIG. 2D, the protruding portion 134 has a rectangular profile and the enhanced portion 140p also has a rectangular profile.

In FIG. 2E, a top portion of the first pillar P1 includes an inclined surface (i.e., a chamfer top), an angle θ3 between the inclined surface and a sidewall of the first pillar P1 is greater than or equal to 110°. In some embodiments, the angle θ3 is less than 180°.

In FIG. 2F, a top portion of first pillar P1 includes a round profile, and a corner radius of the round profile is greater than or equal to a radius of the first pillar P1. In some embodiments, the corner radius of the round profile is at least 0.5 times a corner radius of the first pillar P1.

It could be understood that the first pillar P1, the enhanced portion 140p, and the extension layer 130 of the image sensor 100 in FIG. 1 can be replaced by any of those in FIG. 2B to FIG. 2F.

Referring to FIG. 1, the router layer RL further includes a second pillar layer 180. The second pillar layer 180 includes a plurality of second pillars P2 surrounded by the propagation layer 160 and connecting the transmission layer 170. The second pillars P2 are separated from each other. In some embodiments, materials of the first pillars P1 and the second pillars P2 are the same. In some embodiments, refractive indices of the first pillars P1 and the second pillars P2 are lower than the refractive index of the propagation layer 160. The first pillars P1 and the second pillars P2 are used to distribute the light L of different wavelengths into specific pixels P (shown in FIG. 1).

Referring to FIG. 1, the first pillars P1 and the second pillars P2 are separated by the propagation layer 160 along a thickness direction, and the propagation layer 160 surrounds the first pillars P1 and the second pillars P2 along a transverse direction. In some embodiments, a gap height GH between a top surface of the first pillar P1 and a bottom surface of the second pillar P2 is in a range from 20 nm to 900 nm, such as 100 nm, 300 nm, 500 nm, or 700 nm. When the gap height GH is in the above range, it is beneficial for improving the quantum efficiency of the image sensor 100.

In the embodiments of FIG. 1, each of microstructures 170m of the transmission layer 170 has the same period, size, and shape. Specifically, the microstructures 170m are repeatedly and evenly distributed above the second pillar layer 180. With the arrangement of the microstructures 170m, the surface reflectivity can be reduced and the light energy entering the photodiodes 112 of the photoelectric conversion layer 110 can be increased, thereby increasing the quantum efficiency of the image sensor 100. In some embodiments, a refractive index of the transmission layer 170 is in a range from 1.25 to 2.5, such as 1.3, 1.5, 1.8, 2, 2.2, or 2.4. In some embodiments, a material of the transmission layer 170 is the same as a material of the first pillar layer 150 or the propagation layer 160.

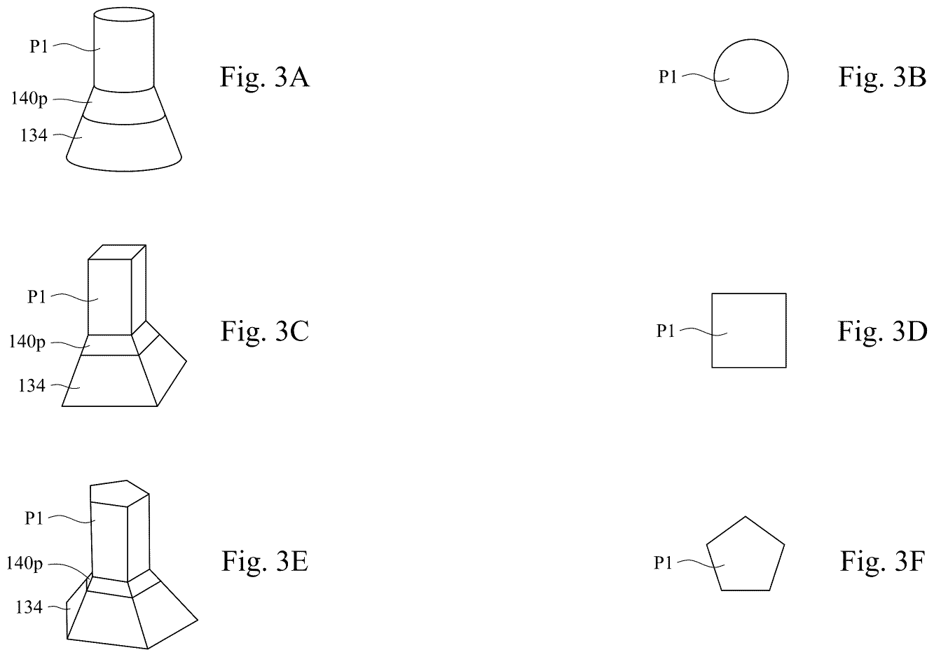

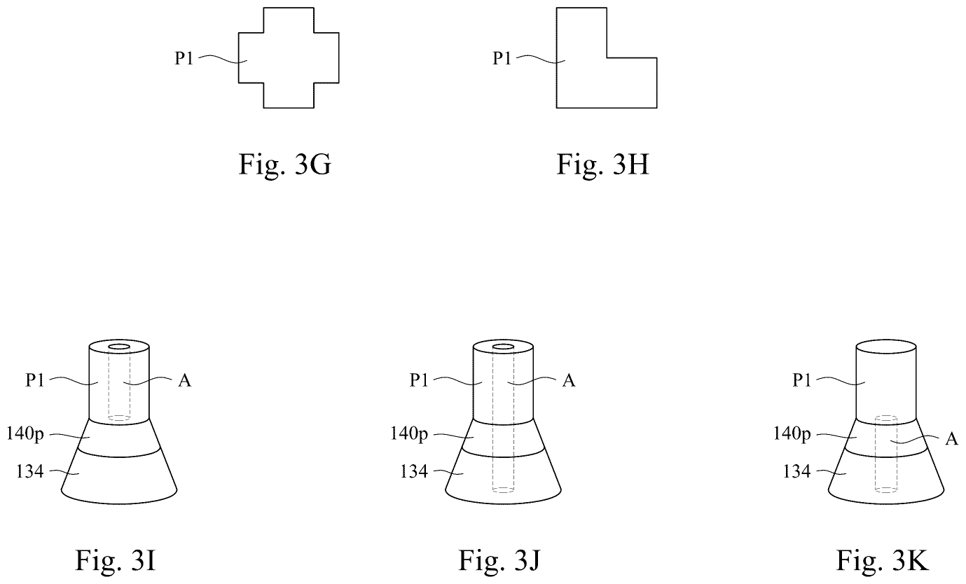

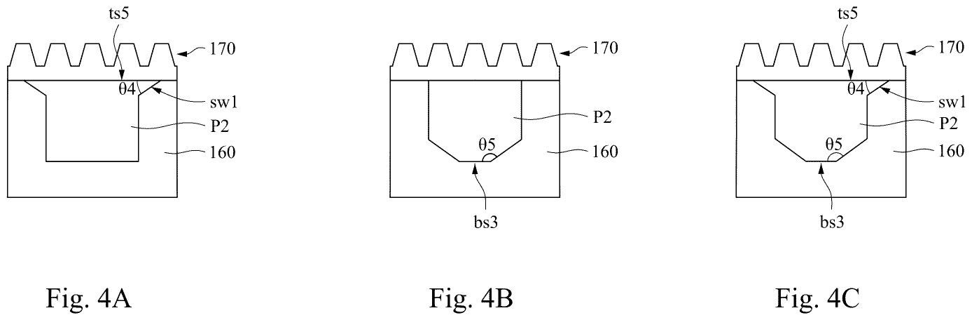

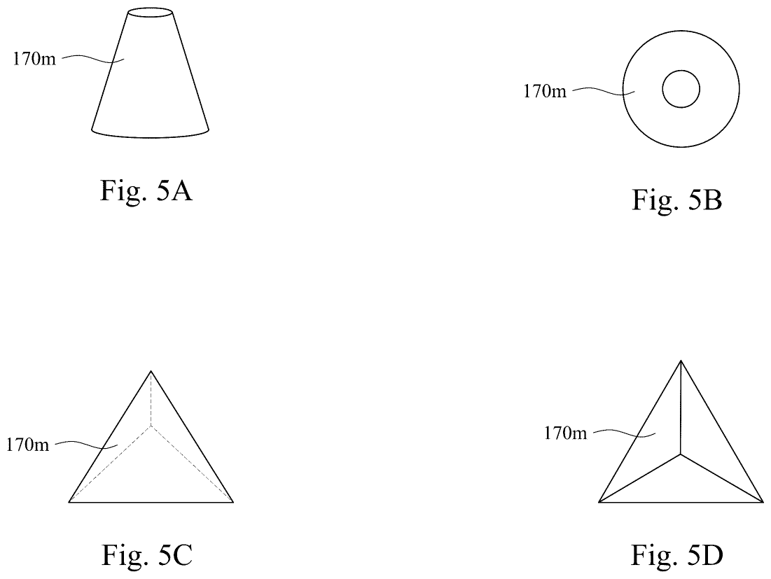

FIG. 3A is a three-dimensional diagram of the first pillar P1, the enhanced portion 140p, and the protruding portion 134 of the image sensor 100 in FIG. 1. FIG. 3B is a top view of the first pillar P1 in FIG. 3A. As shown in FIG. 3A, the first pillar P1 is a cylinder, and the enhanced portion 140p and the protruding portion 134 have circular tables on their tops. The first pillar P1 in FIG. 3A has a circular profile, as shown in FIG. 3B.

FIG. 3C is an alternative example of FIG. 3A. FIG. 3D is a top view of the first pillar P1 in FIG. 3C. As shown in FIG. 3C, the first pillar P1 is a square column, and the enhanced portion 140p and the protruding portion 134 have square tables on their tops. The first pillar P1 in FIG. 3C has a square profile, as shown in FIG. 3D.

FIG. 3E is an alternative example of FIG. 3A. FIG. 3F is a top view of the first pillar P1 in FIG. 3E. As shown in FIG. 3E, the first pillar P1 is a polygonal column, and the enhanced portion 140p and the protruding portion 134 have polygonal tables on their tops. The first pillar P1 in FIG. 3E has a polygonal profile, as shown in FIG. 3F.

FIG. 3G and FIG. 3H are top views of alternative examples of the first pillar P1 in FIG. 3A. In some examples, the first pillar P1 is a cross column, and the enhanced portion 140p and the protruding portion 134 have cross tables on their tops. The first pillar P1 in FIG. 3G has a cross profile. In some examples, the first pillar P1 is an irregular column, and the enhanced portion 140p and the protruding portion 134 have irregular tables on their tops. The first pillar P1 in FIG. 3H has an irregular profile, such as the L shape.

FIG. 3I, FIG. 3J, and FIG. 3K are three-dimensional diagrams of alternative examples of FIG. 3A. In FIG. 3I, an air column A is disposed in the first pillar P1. In FIG. 3J, the air column A is in the first pillar P1, the enhanced portion 140p, and the protruding portion 134. In FIG. 3J, the air column A is in the enhanced portion 140p and the protruding portion 134.

It could be understood that the first pillar P1, the enhanced portion 140p, and the protruding portion 134 of the image sensor 100 in FIG. 1 can be replaced by any of those in FIG. 3C, FIG. 3E, FIG. 3I, FIG. 3J, and FIG. 3K.

FIG. 4A, FIG. 4B, and FIG. 4C are alternative examples of the second pillar P2 in FIG. 1. In FIG. 4A, the second pillar P2 has an outward extending sidewall sw1, and an angle θ4 between the outward extending sidewall sw1 and a top surface ts5 of the second pillar P2 is in a range from 45° to 90°, such as 50°, 60°, 70°, or 80°.

In FIG. 4B, a bottom portion of the second pillar P2 includes an inclined surface (i.e., a chamfer bottom), and an angle θ5 between the inclined surface and a bottom surface bs5 of the second pillar is greater than or equal to 110°. In some embodiments, the angle θ5 is less than 180°.

In FIG. 4C, the angle θ4 between the outward extending sidewall sw1 and the top surface ts5 of the second pillar P2 is in a range from 45° to 90°, such as 50°, 60°, 70°, or 80°. The bottom portion of the second pillar P2 includes the inclined surface (i.e., a chamfer bottom), and the angle θ5 between the inclined surface and the bottom surface bs3 of the second pillar is greater than or equal to 110°. In some embodiments, the angle θ5 is less than 180°.

It could be understood that the second pillar P2 of the image sensor 100 in FIG. 1 can be replaced by any of those in FIG. 4A, FIG. 4B, and FIG. 4C.

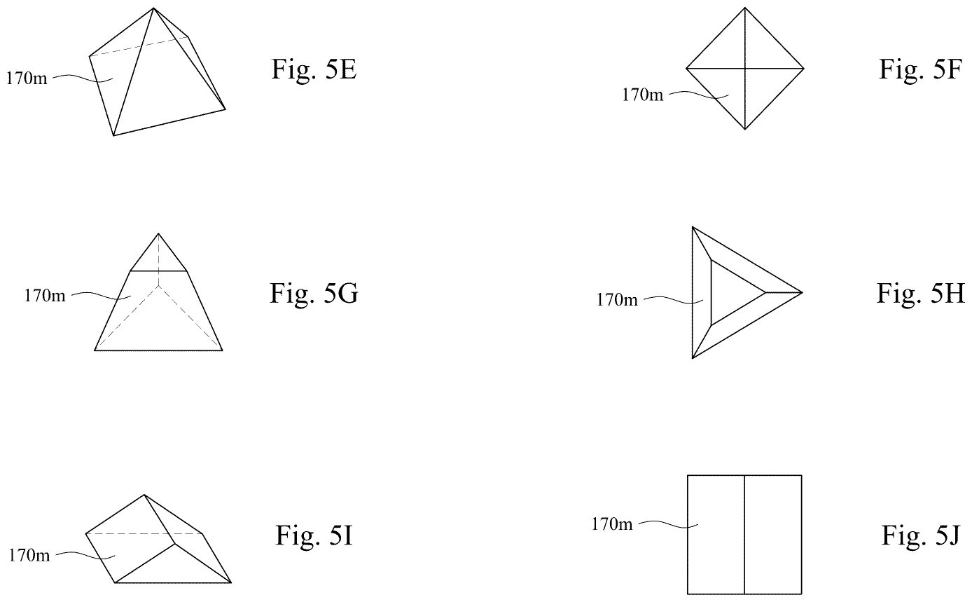

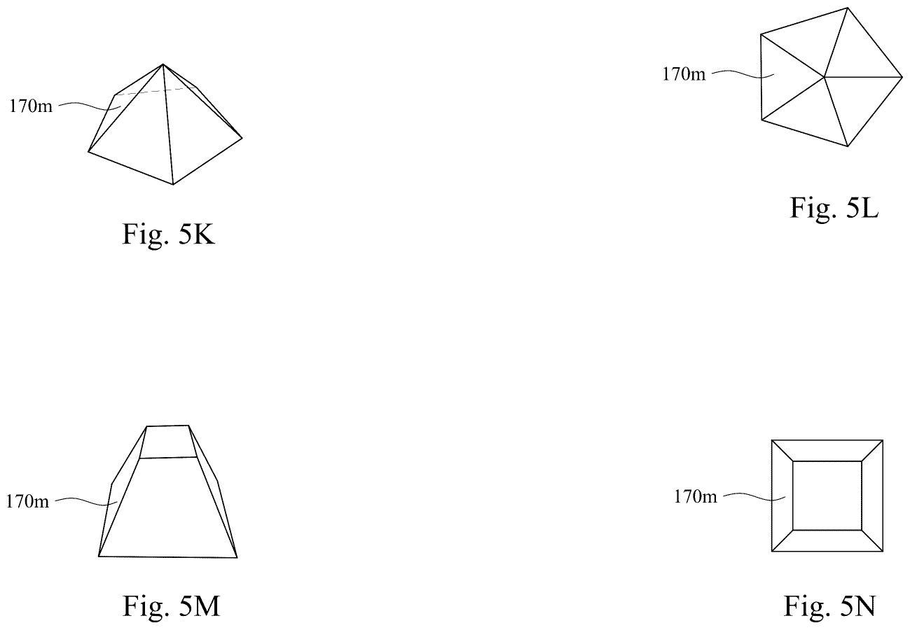

FIG. 5A is a three-dimensional diagram of the microstructure 170m in FIG. 1. FIG. 5B is a top view of the microstructure 170m in FIG. 5A. As shown in FIG. 5A, the microstructure 170m is a truncated cone. The microstructure 170m in FIG. 5A in the top view includes a circular shape, as shown in FIG. 5B.

FIG. 5C is an alternative example of the microstructure 170m in FIG. 5A. FIG. 5D is a top view of the microstructure 170m in FIG. 5C. As shown in FIG. 5C, the microstructure 170m is a tetrahedron. The microstructure 170m in FIG. 5C in the top view includes a triangular shape, as shown in FIG. 5D.

FIG. 5E is an alternative example of the microstructure 170m in FIG. 5A. FIG. 5F is a top view of the microstructure 170m in FIG. 5E. As shown in FIG. 5E, the microstructure 170m is a pentahedron. The microstructure 170m in FIG. 5E in the top view includes a rectangular shape, as shown in FIG. 5F.

FIG. 5G is an alternative example of the microstructure 170m in FIG. 5A. FIG. 5H is a top view of the microstructure 170m in FIG. 5G. As shown in FIG. 5G, the microstructure 170m is a pentahedron. The microstructure 170m in FIG. 5G in the top view includes a triangular shape, as shown in FIG. 5H.

FIG. 5I is an alternative example of the microstructure 170m in FIG. 5A. FIG. 5J is a top view of the microstructure 170m in FIG. 5I. As shown in FIG. 5I, the microstructure 170m is a pentahedron. The microstructure 170m in FIG. 5I in the top view includes a rectangular shape, as shown in FIG. 5J.

FIG. 5K is an alternative example of the microstructure 170m in FIG. 5A. FIG. 5L is a top view of the microstructure 170m in FIG. 5K. As shown in FIG. 5K, the microstructure 170m is a hexahedron. The microstructure 170m in FIG. 5K in the top view includes a hexagonal shape, as shown in FIG. 5L.

FIG. 5M is an alternative example of the microstructure 170m in FIG. 5A. FIG. 5N is a top view of the microstructure 170m in FIG. 5M. As shown in FIG. 5M, the microstructure 170m is a hexahedron. The microstructure 170m in FIG. 5M in the top view includes a rectangular shape, as shown in FIG. 5N.

In other embodiments, the microstructure 170m may be a polyhedron structure. It could be understood that the types of microstructure 170m can be chosen according to the pixel arrangement of the image sensor 100.

Referring to FIG. 1, the photoelectric conversion layer 110 further includes a plurality of photodiodes 112 and a plurality of deep trench isolations 114 separating the photodiodes 112. A pixel P is determined by a distance between midlines of adjacent two of the deep trench isolations 114. The color filter layer 120 further includes a plurality of color filters 122 and 124, in which the color filter 122 is different from color filter 124.

In the embodiment of FIG. 1, one color filter corresponds to one pixel P and at least one first pillar P1. However, in other embodiments, one color filter may correspond to a plurality of pixels P and a number of first pillars P1.

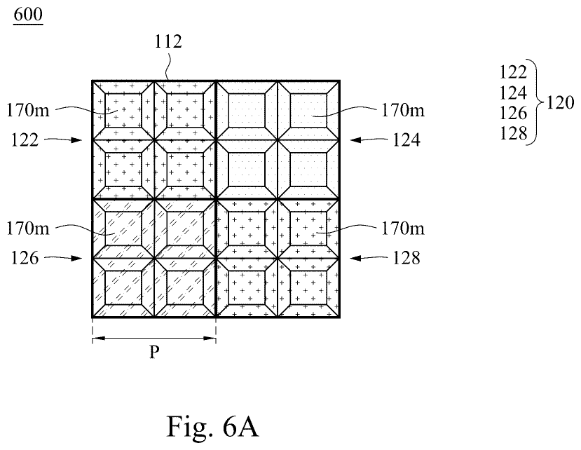

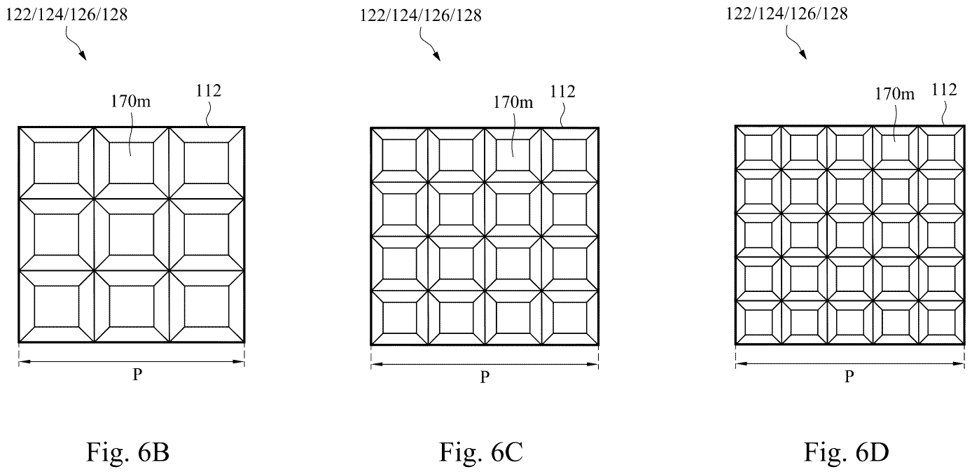

FIG. 6A is a top view of an image sensor 600 according some embodiments of the present disclosure, in which merely the microstructures 170m and the color filter layer 120 are shown for clarity. The image sensor 600 in FIG. 6A is similar to the image sensor 100 in FIG. 1, except the numbers and arrangements of microstructures 170m. The image sensor 600 includes a plurality of color filters 122, 124, 126, and 128. It can be understood that each of the color filters 122, 124, 126, and 128 corresponds to one photodiode 112 and one pixel P. In the embodiment of FIG. 6A, one pixel P corresponds to 4 microstructures 170m (of the transmission layer 170, referring to FIG. 1), in which the microstructures 170m is arranged in a 2×2 array. In some embodiments, the color filters 122, 124, 126, and 128 are applicable to RGGB, RGBW, CMY, RYYB, and RGBIR configurations.

FIG. 6B, FIG. 6C, and FIG. 6D are top views of alternative examples of the image sensor 600 in FIG. 6A. In FIG. 6B, one pixel P corresponds to 9 microstructures 170m, in which the microstructures 170m is arranged in a 3×3 array. In FIG. 6C, one pixel P corresponds to 16 microstructures 170m, in which the microstructures 170m is arranged in a 4×4 array. In FIG. 6D, one pixel P corresponds to 25 microstructures 170m, in which the microstructures 170m is arranged in a 5×5 array.

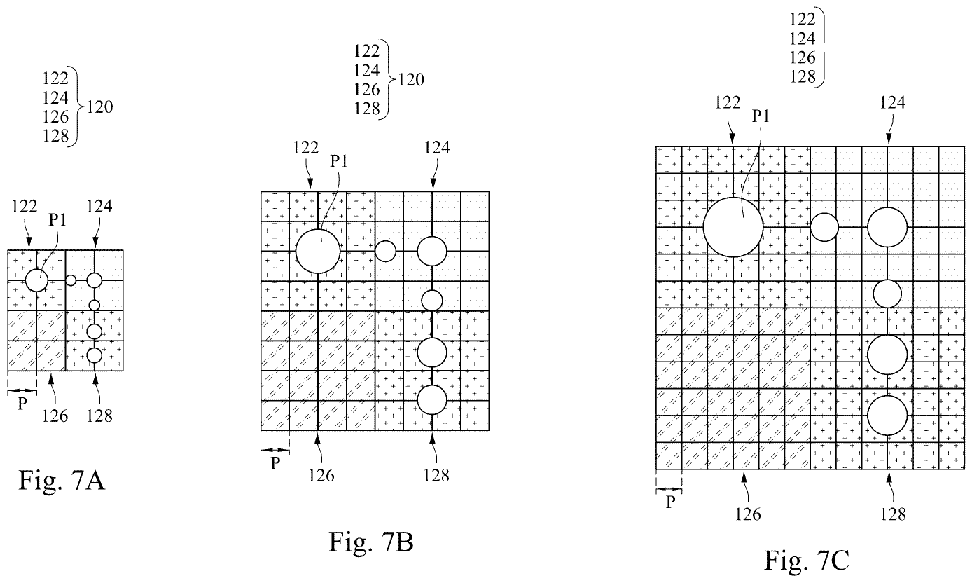

FIG. 7A, FIG. 7B, and FIG. 7C are top views of the first pillars P1 and the color filter layer 120 according some embodiments of the present disclosure. It could be understood that each of the color filters 122, 124, 126, and 128 in the embodiments of FIG. 7A, FIG. 7B, and FIG. 7C includes a plurality of pixels and each of the first pillars P1 spans across a plurality of pixels. In FIG. 7A, each of the color filters 122, 124, 126, and 128 includes 4 pixels. In FIG. 7B, each of the color filters 122, 124, 126, and 128 includes 16 pixels. In FIG. 7C, each of the color filters 122, 124, 126, and 128 includes 36 pixels.

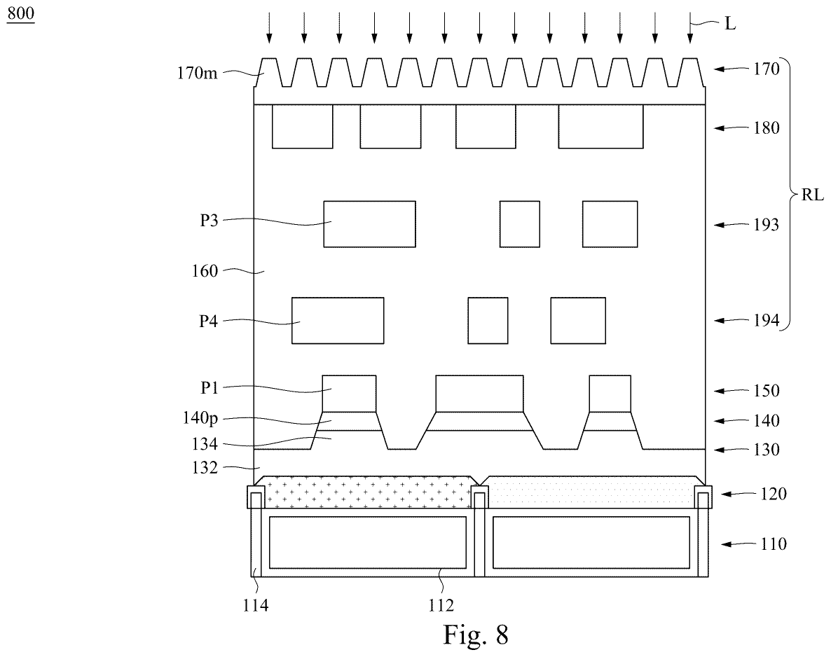

FIG. 8 is a cross-sectional view of an image sensor 800 according some embodiments of the present disclosure. The image sensor 800 in FIG. 8 is similar to the image sensor 100 in FIG. 1, except that the router layer RL in FIG. 8 further includes a third pillar layer 193 and a fourth layer 194. The third pillar layer 193 includes a plurality of third pillars P3 surrounded by the propagation layer 160. The fourth layer 194 includes a plurality of fourth pillars P4 surrounded by the propagation layer 160. The first pillars P1, the second pillars P2, the third pillars P3, and the fourth pillars P4 are spaced form each other. In some embodiments, the materials of the first pillars P1, the second pillars P2, the third pillars P3, and the fourth pillars P4 are the same.

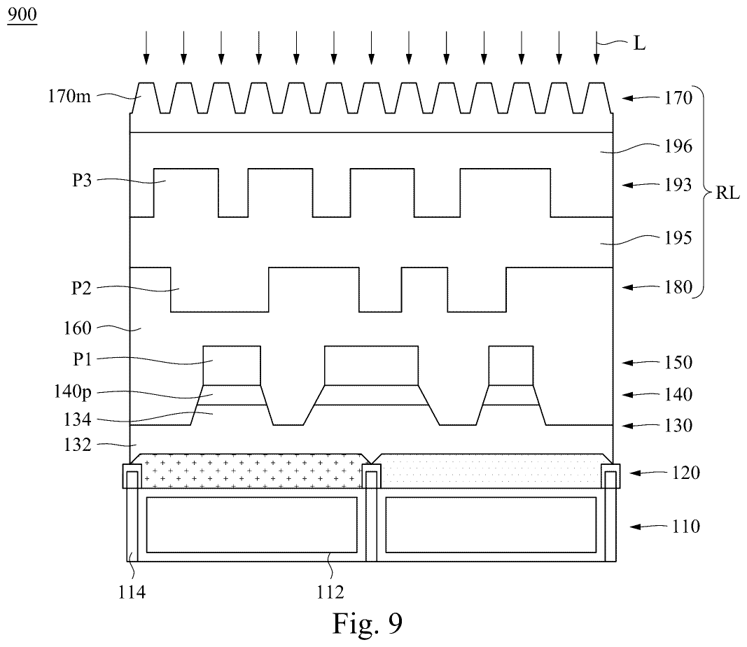

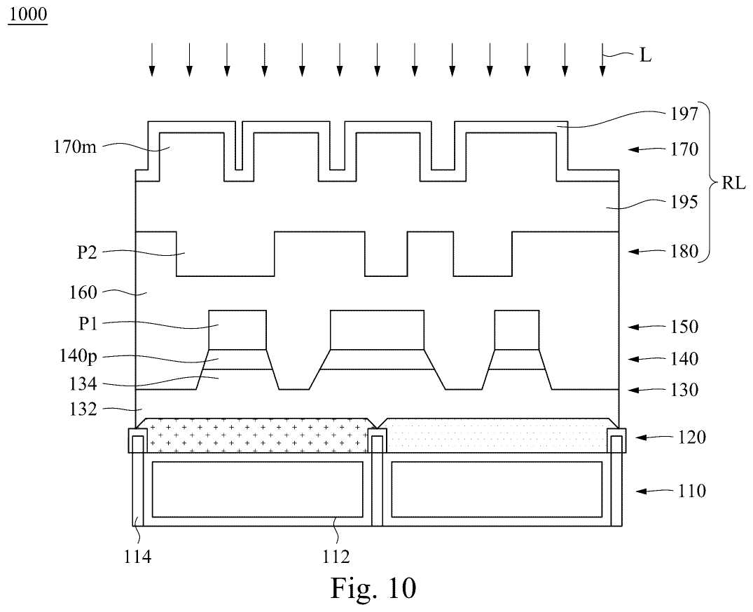

FIG. 9 is a cross-sectional view of an image sensor 900 according some embodiments of the present disclosure. The image sensor 900 in FIG. 9 is similar to the image sensor 100 in FIG. 1, except that the router layer RL in FIG. 10 further includes a transverse layer 195, a third pillar layer 193, and an additional propagation layer 196. The transverse layer 195 is disposed on the second pillar layer 180. The third pillar layer 193 includes a plurality of third pillars P3 disposed on the transverse layer 195, in which the third pillars P3 are separated from each other. In other words, the second pillars P2 and the third pillars P3 are separated by the transverse layer 195. Specifically, the second pillars P2 and the third pillars P3 are disposed on two sides of the transverse layer 195. The additional propagation layer 196 is disposed on the transverse layer 195 and surrounds the third pillars P3. In some embodiments, materials of the transverse layer 195, the first pillar layer 150, the second pillar layer 180, and the third pillar layer 193 are the same. In some embodiments, the materials of the propagation layer 160 and the additional propagation layer 196 are the same.

FIG. 10 is a cross-sectional view of an image sensor 1000 according some embodiments of the present disclosure. The router layer RL further includes an anti-reflection layer 197 and a transverse layer 195. The anti-reflection layer 197 is conformally disposed on the transmission layer 170. In other words, a recess is still presented two of the microstructures 170m, as shown in FIG. 10. The transverse layer 195 is under the transmission layer 170 and connects the transmission layer 170. In other words, the second pillars P2 and the microstructures 170m are separated by the transverse layer 195. Specifically, the second pillars P2 and the microstructures 170m are disposed on two sides of the transverse layer 195. In some embodiments, materials of the transverse layer 195, the first pillar layer 150, the second pillar layer 180, and the transmission layer 170 are the same. In some embodiments, a refractive index of the transmission layer 170 is greater than a refractive index of the anti-reflection layer 197.

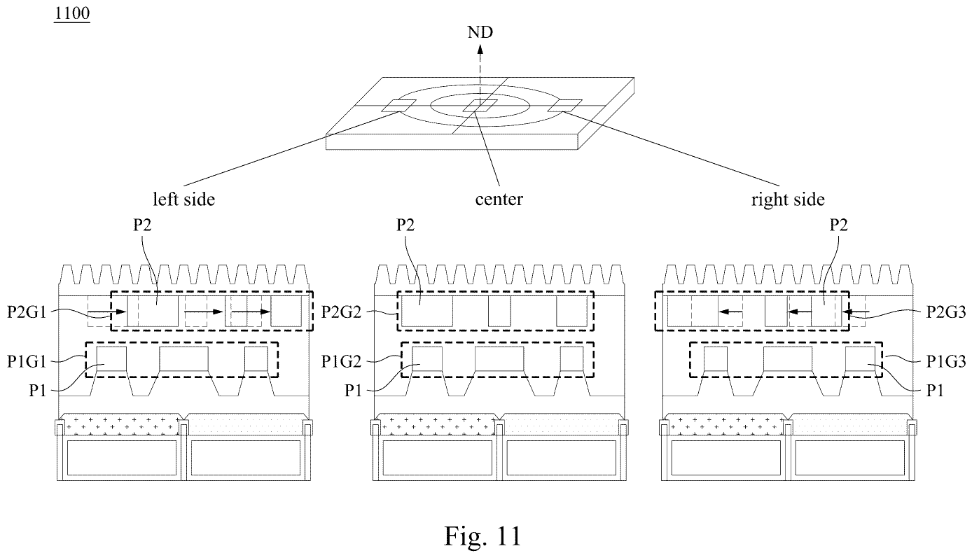

FIG. 11 is a schematic diagram of an image sensor 1100 according some embodiments of the present disclosure. As shown in FIG. 11, the second pillars P2 include a first group P2G1 of the second pillars P2 disposed on a die edge (left side) of the image sensor 1100 and a second group P2G2 of the second pillars P2 disposed on a die center of the image sensor 1100, the first pillars P1 include a first group P1G1 of the first pillars P1 disposed on the die edge (left side) of the image sensor 1100 and a second group P1G2 of the first pillars P1 disposed on the die center of the image sensor 1100, a center of the first group P2G1 of the second pillars P2 is offset relative to a center of the first group P1G1 of the first pillars P1 in a normal direction ND, and a center of the second group P2G2 of the second pillars P2 is aligned with a center of the second group P1G2 of the first pillars P1 in the normal direction.

Similarly, as shown in FIG. 11, the second pillars P2 include a third group P2G3 of the second pillars P2 disposed on a die edge (right side) of the image sensor 1100, the first pillars P1 include a third group P1G3 of the first pillars P1 disposed on the die edge (right side) of the image sensor 1100, a center of the third group P2G3 of the second pillars P2 is offset relative to a center of the third group P1G3 of the first pillars P1 in the normal direction ND.

In summary, the image sensor of the present disclosure has the transmission layer, the propagation layer, the first pillar layer, the enhanced layer, and the extension layer. The microstructures of the transmission layer can reduce the external light to be reflected. The propagation layer surrounds the first pillars of the first pillar layer, the enhanced portions of the enhanced layer, and the protruding portions of the extension layer, so that the quantum efficiency of the image sensor can be improved. In addition, the shape of the enhanced portion follows the shape of the first pillar and the shape of the protruding portion, therefore the refractive index differences different layers can be decreased and so the quantum efficiency of the image sensor can be increased.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An image sensor, comprising:
a photoelectric conversion layer;
a color filter layer disposed on the photoelectric conversion layer;
an extension layer disposed on the color filter layer;
an enhanced layer comprising a plurality of enhanced portions disposed on the extension layer;
a first pillar layer comprising a plurality of first pillars disposed on the enhanced layer, wherein each of the first pillars corresponds to each of the enhanced portions;
a propagation layer disposed on the extension layer and the first pillar layer, wherein the propagation layer surrounds the first pillars and the enhanced portions; and
a router layer disposed on the propagation layer, wherein the router layer comprises a transmission layer comprising a plurality of microstructures, wherein a height of each of the enhanced portions satisfies the following formula:
$$0.02 \times λ \leq {H}_{E N P} \leq 0.85 \times {H}_{P 1} - 40 ,$$
wherein λ is a wavelength of an external light, H_{ENP} is the height of each of the enhanced portions, and H_{P1} is a height of each of the first pillars.

2. The image sensor of claim 1, wherein a bottom surface of one of the first pillars contacts a top surface of one of the enhanced portions, and a bottom surface area of one of the first pillars is substantially the same as a top surface area of one of the enhanced portions.

3. The image sensor of claim 1, wherein a refractive index of the propagation layer is less than or equal to a refractive index of the extension layer, a refractive index of the propagation layer is in a range from 1.2 to 1.7, a maximum height of the extension layer is in a range from 100 nm to 2800 nm, and a refractive index of the transmission layer is in a range from 1.25 to 2.5.

4. The image sensor of claim 1, wherein a refractive index of the enhanced layer satisfies the following formula:
$${( {n}_{P 1} \times {n}_{E X} - 1.4 )}^{0.5} \leq {n}_{E N} \leq {( {n}_{P 1} \times {n}_{E X} + 1.6 )}^{0.5} ,$$
wherein n_{P1} is a refractive index of the first pillar layer, n_{EX} is a refractive index of the extension layer, and n_{EN} is the refractive index of the enhanced layer.

5. The image sensor of claim 1, wherein the extension layer comprises a main portion and a plurality of protruding portions protruding from the main portion, wherein the main portion is disposed between the protruding portions and the color filter layer, and each of the protruding portions corresponds to each of the enhanced portions, and
wherein the propagation layer disposed on the main portion and surrounds the protruding portions.

6. The image sensor of claim 5, wherein a bottom surface of one of enhanced portions contacts a top surface of one of the protruding portions, and a bottom surface area of one of the enhanced portions is substantially the same as a top surface area of one of the protruding portions.

7. The image sensor of claim 5, wherein each of the protruding portions has a trapezoidal profile, and an angle between a sidewall and a top surface of each of the enhanced portions is in a range from 90° and 135°.

8. The image sensor of claim 5, wherein each of the enhanced portions has a trapezoidal profile, and an angle between a top surface of the main portion and a sidewall of each of the protruding portions is 90°.

9. The image sensor of claim 5, wherein an angle between a sidewall and a top surface of each of the enhanced portions is 90°, and an angle between a top surface of the main portion and a sidewall of each of the protruding portions is 90°.

10. The image sensor of claim 1, wherein a top portion of each of the first pillars comprises an inclined surface, an angle between the inclined surface and a sidewall of the each of the first pillars is greater than or equal to 110°.

11. The image sensor of claim 1, wherein a top portion of each of the first pillars comprises a round profile, and a corner radius of the round profile is greater than or equal to a radius of each of the first pillars.

12. The image sensor of claim 1, wherein the router layer further comprises a second pillar layer comprising a plurality of second pillars surrounded by the propagation layer and connecting the transmission layer, the second pillar layer satisfies one of the following conditions:
each of the second pillars has an outward extending sidewall, and an angle between the outward extending sidewall and a top surface of the each of the second pillars is in a range from 45° to 90°; or
a bottom portion of each of the second pillars comprises an inclined surface, and an angle between the inclined surface and a bottom surface of the each of the second pillars is greater than or equal to 110°.

13. The image sensor of claim 1, wherein the router layer further comprises a second pillar layer comprising a plurality of second pillars surrounded by the propagation layer and connecting the transmission layer, each of the second pillars has an outward extending sidewall, an angle between the outward extending sidewall and a top surface of the each of the second pillars is in a range from 45° to 90°, a bottom portion of each of the second pillars comprises an inclined surface, and an angle between the inclined surface and a bottom surface of the each of the second pillars is greater than or equal to 110°.

14. The image sensor of claim 1, wherein each of the first pillars is a cylinder, a square column, a polygonal column, a cross column, an irregular column, or a hollow column, and each of the microstructures is a truncated cone, a tetrahedron, a pentahedron, or a hexahedron.

15. The image sensor of claim 1, wherein the router layer further comprises a second pillar layer comprising a plurality of second pillars surrounded by the propagation layer and connecting the transmission layer,
wherein the router layer further comprises a third pillar layer comprising a plurality of third pillars surrounded by the propagation layer and a fourth layer comprising a plurality of fourth pillars surrounded by the propagation layer, and
wherein the first pillars, the second pillars, the third pillars, and the fourth pillars are spaced form each other.

16. The image sensor of claim 1, wherein the router layer further comprises:
a second pillar layer comprising a plurality of second pillars surrounded by the propagation layer;
a transverse layer disposed on the second pillar layer;
a third pillar layer comprising a plurality of third pillars disposed on the transverse layer; and
an additional propagation layer disposed on the transverse layer and surrounding the third pillars, wherein materials of the transverse layer, the first pillar layer, the second pillar layer, and the third pillar layer are the same.

17. The image sensor of claim 1, wherein the router layer further comprises:
an anti-reflection layer conformally disposed on the transmission layer;
a transverse layer under the transmission layer and connecting the transmission layer; and
a second pillar layer comprising a plurality of second pillars surrounded by the propagation layer, wherein materials of the transverse layer, the first pillar layer, the second pillar layer, and the transmission layer are the same, and a refractive index of the transmission layer is greater than a refractive index of the anti-reflection layer.

18. The image sensor of claim 1, wherein the photoelectric conversion layer comprises a plurality of photodiodes and a plurality of deep trench isolations separating the photodiodes, a pixel is determined by a distance between midlines of adjacent two of the deep trench isolations, the pixel corresponds to 4, 9, 16, or 25 microstructures of the transmission layer, and the microstructures are arranged in an array.

19. The image sensor of claim 1, wherein the router layer further comprises a second pillar layer comprising a plurality of second pillars surrounded by the propagation layer and connecting the transmission layer,
wherein the second pillars comprise a first group of the second pillars disposed on a die edge of the image sensor and a second group of the second pillars disposed on a die center of the image sensor, the first pillars comprise a first group of the first pillars disposed on the die edge of the image sensor and a second group of the first pillars disposed on the die center of the image sensor, a center of the first group of the second pillars is offset relative to a center of the first group of the first pillars in a normal direction, and a center of the second group of the second pillars is aligned with a center of the second group of the first pillars in the normal direction.

20. The image sensor of claim 1, wherein the photoelectric conversion layer comprises a plurality of photodiodes and a plurality of deep trench isolations separating the photodiodes, a pixel is determined by a distance between midlines of adjacent two of the deep trench isolations, and each of the first pillars spans across a plurality of pixels.
